(19) United States
(12) Patent Application Publication
(10) Pub. No.: US 2024/0046003 A1
(43) Pub. Date: Feb. 8, 2024

(54) DIGITAL TWIN SIMULATION OF VEHICLE OBJECT LOADING

(71) Applicant: INTERNATIONAL BUSINESS MACHINES CORPORATION, ARMONK, NY (US)

(72) Inventors: Shailendra Moyal, Pune (IN); Sarbajit K. Rakshit, Kolkata (IN); Akash U. Dhoot, Pune (IN)

(21) Appl. No.: 17/816,738

(22) Filed: Aug. 2, 2022

(51) Int. Cl. G06F 30/20; G06Q 50/30

(52) U.S. Cl. CPC G06F 30/20; G06Q 50/30

(57) ABSTRACT

According to one embodiment, a method, computer system, and computer program product for static balancing of a cargo transport through digital twin simulation is provided. The embodiment may include capturing a plurality of property data related to a transport. The embodiment may further include capturing a plurality of property data related to a plurality of cargo items. The embodiment may also include generating a digital twin simulation of the transport and each cargo item. The embodiment may further include generating a loading plan of each cargo item onto the transport based on the generated digital twin simulation.

### BACKGROUND

The present invention relates generally to the field of computing, and more particularly to static balancing.

Static balancing relates to a process of ensuring an object is properly weighted and/or aligned to allow the object to remain in place even while motion occurs. Static balancing works by calculating a center of gravity for an object is on the axis of rotation. Prior to more sophisticated methods, statically balancing an object involved providing support for an object along an axis of rotation and observing if the object rotated so that the heaviest side of the object came to rest at the bottom. If the object rotated, weight may be added to the top of the object or the bottom may be evenly whittled down to evenly distribute the load. The object would be considered statically balanced along the axis of rotation when the object no longer rotated regardless of the side facing up. A real-world example of static balancing may be observed through vehicle wheels where weights are added to compensate for balancing imperfections that can cause shaking or rattling when the vehicle travels.

### SUMMARY

According to one embodiment, a method, computer system, and computer program product for static balancing of a cargo transport through digital twin simulation is provided. The embodiment may include capturing a plurality of property data related to a transport. The embodiment may further include capturing a plurality of property data related to a plurality of cargo items. The embodiment may also include generating a digital twin simulation of the transport and each cargo item. The embodiment may further include generating a loading plan of each cargo item onto the transport based on the generated digital twin simulation.

### BRIEF DESCRIPTION OF THE SEVERAL VIEWS OF THE DRAWINGS

These and other objects, features and advantages of the present invention will become apparent from the following detailed description of illustrative embodiments thereof, which is to be read in connection with the accompanying drawings. The various features of the drawings are not to scale as the illustrations are for clarity in facilitating one skilled in the art in understanding the invention in conjunction with the detailed description. In the drawings:

FIG. 1 illustrates an exemplary networked computer environment according to at least one embodiment.

FIG. 2 illustrates an operational flowchart for a cargo loading digital twin simulation process according to at least one embodiment.

FIG. 3 is an exemplary block diagram of digital twin simulation for a cargo loading system according to at least one embodiment.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

Embodiments of the present invention relate to the field of computing, and more particularly to static balancing. The following described exemplary embodiments provide a system, method, and program product to, among other things, perform static balancing of a cargo transport through digital twin simulation. A digital twin is a virtual model of a physical entity that mirrors the characteristics of the item it represents. Therefore, the present embodiment has the capacity to improve the technical field of static balancing by allowing for intentional placement of the center of gravity for a transport through precision loading of cargo items thereby reducing disproportionate and/or excessive wear on transport components.

A digital twin relates to a virtual model designed to closely correspond with a physical object. The physical object may, typically, be outfitted with various sensors to capture data related to key functionality areas. In turn, the affixed sensors gather data regarding aspects of the physical object's performance and characteristics over time. This key information can be used to recreate the physical object in a digital form (i.e., a digital model of the physical object) that allows for exposure to and analysis of the impact on performance and possible improvements to the physical object when exposed to different simulation environments.

As previously described, static balancing relates to a process of ensuring an object is properly weighted and/or aligned to allow the object to remain in place even while motion occurs. Static balancing works by calculating a center of gravity for an object is on the axis of rotation. Prior to more sophisticated methods, statically balancing an object involved providing support for an object along an axis of rotation and observing if the object rotated so that the heaviest side of the object came to rest at the bottom. If the object rotated, weight may be added to the top of the object or the bottom may be evenly whittled down to evenly distribute the load. The object would be considered statically balanced along the axis of rotation when the object no longer rotated regardless of the side facing up. A real-world example of static balancing may be observed through vehicle wheels where weights are added to compensate for balancing imperfections that can cause shaking or rattling when the vehicle travels.

With the proliferation of computer methods, static balancing may be performed without requiring the rotation of an object along an axis. A set of sensors or a bubble level to have typically been implemented to calculate the center of gravity of an object. However, digital twin modelling or simulation may result in a more accurate and efficient technique for calculating an object's center of gravity in certain circumstances.

For example, transportation vehicles carry many different types of objects from one location to another daily. The objects loaded into a transport may have different shapes, dimensions, and weights. Similarly, these various shapes, dimensions, and weights may result in any number of different placements of the center of gravity for each object. When loaded objects are stacked atop each other, the resultant center of gravity may also change.

The physical object carrying capacity of a transport is highly dependent on the various aspects of the vehicle's current condition. For example, different wheel suspension systems may have different weight capacities. Improper loading of the physical objects on the transport may result in damage or excessive wear in one or more portions of the vehicle due to unbalanced forces. As such, it may be advantageous to, among other things, utilize digital twin simulation of a transport and its cargo to aid in determining the overall strength of the transport, the status of various transport components, and calculating the center of gravity of the transport as well as the cargo being loaded.

According to at least one embodiment, various data points related to an item of cargo, such as dimension, shape, weight, and center of gravity, may be captured and/or calculated during movement of the cargo items to a transport. Taking into account various status-related items of the transport, a plan for placement of each cargo item into the transport may be generated, through digital twin simulation of the transport and cargo items, so as to allow for even wear on transport components and place the resultant center of gravity of the fully loaded transport in an optimal location.

Various aspects of the present disclosure are described by narrative text, flowcharts, block diagrams of computer systems and/or block diagrams of the machine logic included in computer program product (CPP) embodiments. With respect to any flowcharts, depending upon the technology involved, the operations can be performed in a different order than what is shown in a given flowchart. For example, again depending upon the technology involved, two operations shown in successive flowchart blocks may be performed in reverse order, as a single integrated step, concurrently, or in a manner at least partially overlapping in time.

A computer program product embodiment (“CPP embodiment” or “CPP”) is a term used in the present disclosure to describe any set of one, or more, storage media (also called “mediums”) collectively included in a set of one, or more, storage devices that collectively include machine readable code corresponding to instructions and/or data for performing computer operations specified in a given CPP claim. A “storage device” is any tangible device that can retain and store instructions for use by a computer processor. Without limitation, the computer readable storage medium may be an electronic storage medium, a magnetic storage medium, an optical storage medium, an electromagnetic storage medium, a semiconductor storage medium, a mechanical storage medium, or any suitable combination of the foregoing. Some known types of storage devices that include these mediums include: diskette, hard disk, random access memory (RAM), read-only memory (ROM), erasable programmable read-only memory (EPROM or Flash memory), static random access memory (SRAM), compact disc read-only memory (CD-ROM), digital versatile disk (DVD), memory stick, floppy disk, mechanically encoded device (such as punch cards or pits/lands formed in a major surface of a disc) or any suitable combination of the foregoing. A computer readable storage medium, as that term is used in the present disclosure, is not to be construed as storage in the form of transitory signals per se, such as radio waves or other freely propagating electromagnetic waves, electromagnetic waves propagating through a waveguide, light pulses passing through a fiber optic cable, electrical signals communicated through a wire, and/or other transmission media. As will be understood by those of skill in the art, data is typically moved at some occasional points in time during normal operations of a storage device, such as during access, de-fragmentation or garbage collection, but this does not render the storage device as transitory because the data is not transitory while it is stored.

Any advantages listed herein are only examples and are not intended to be limiting to the illustrative embodiments. Additional or different advantages may be realized by specific illustrative embodiments. Furthermore, a particular illustrative embodiment may have some, all, or none of the advantages listed above.

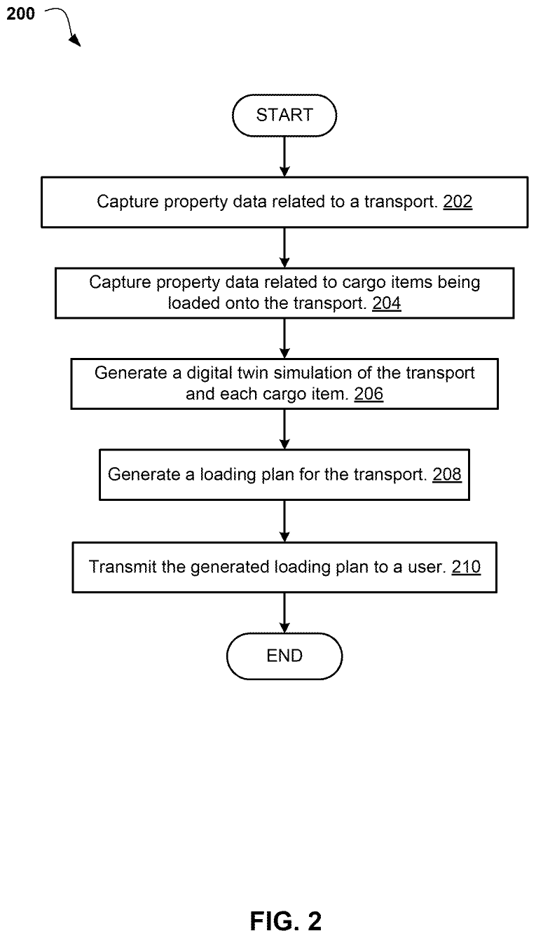

Computing environment 100 contains an example of an environment for the execution of at least some of the computer code involved in performing the inventive methods, such as cargo loading digital twin simulation program 150. In at least one embodiment, cargo loading digital twin simulation program 150 may analyze various data related to cargo items being loaded to a transport and generate a plan to load the cargo items so as that the resultant center of gravity for the fully loaded transport is in a preconfigured location with a minimum impact on wear to the transport and its components. The cargo loading digital twin simulation method is explained in more detail below with respect to FIG. 2. In addition to cargo loading digital twin simulation program 150, computing environment 100 includes, for example, computer 101, wide area network (WAN) 102, end user device (EUD) 103, remote server 104, public cloud 105, and private cloud 106. In this embodiment, computer 101 includes processor set 110 (including processing circuitry 120 and cache 121), communication fabric 111, volatile memory 112, persistent storage 113 (including operating system 122 and cargo loading digital twin simulation program 150, as identified above), peripheral device set 114 (including user interface (UI), device set 123, storage 124, and Internet of Things (IoT) sensor set 125), and network module 115. Remote server 104 includes remote database 130. Public cloud 105 includes gateway 140, cloud orchestration module 141, host physical machine set 142, virtual machine set 143, and container set 144. Furthermore, notwithstanding depiction in computer 101, cargo loading digital twin simulation program 150 may be stored in and/or executed by, individually or in any combination, end user device 103, remote server 104, public cloud 105, and private cloud 106.

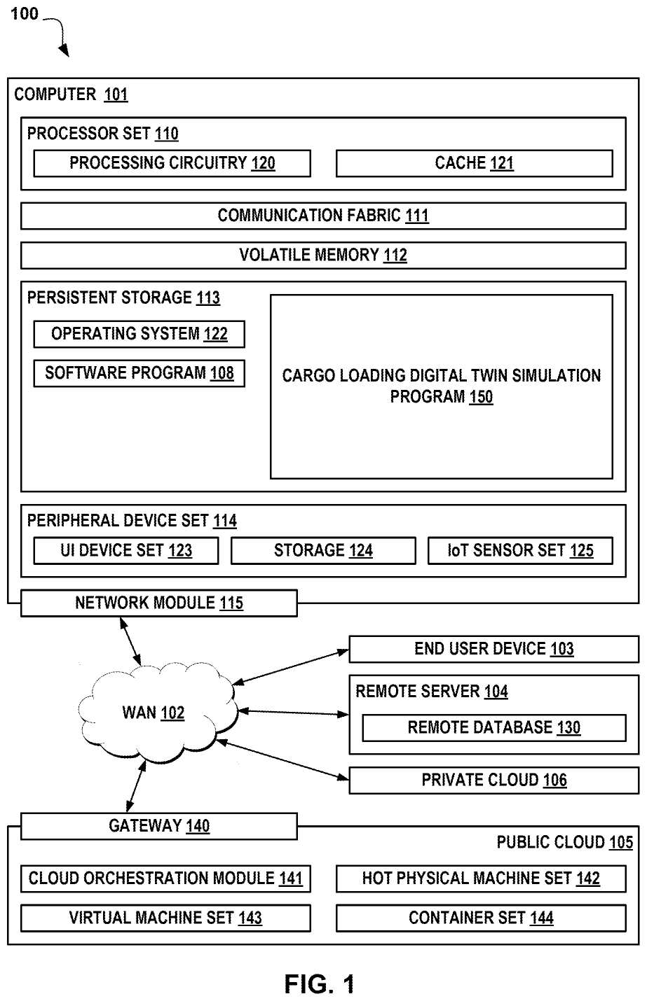

Computer 101 may take the form of a desktop computer, laptop computer, tablet computer, smart phone, smart watch or other wearable computer, mainframe computer, quantum computer, a robotic, or otherwise unmanned, cargo loading device, or any other form of computer or mobile device now known or to be developed in the future that is capable of running a program, such as software program 108, and accessing a network or querying a database, such as remote database 130. As is well understood in the art of computer technology, and depending upon the technology, performance of a computer-implemented method may be distributed among multiple computers and/or between multiple locations. On the other hand, in this presentation of computing environment 100, detailed discussion is focused on a single computer, specifically computer 101, for illustrative brevity. Computer 101 may be located in a cloud, even though it is not shown in a cloud in FIG. 1. On the other hand, computer 101 is not required to be in a cloud except to any extent as may be affirmatively indicated.

Processor set 110 includes one, or more, computer processors of any type now known or to be developed in the future. Processing circuitry 120 may be distributed over multiple packages, for example, multiple, coordinated integrated circuit chips. Processing circuitry 120 may implement multiple processor threads and/or multiple processor cores. Cache 121 is memory that is located in the processor chip package(s) and is typically used for data or code that should be available for rapid access by the threads or cores running on processor set 110. Cache memories are typically organized into multiple levels depending upon relative proximity to the processing circuitry. Alternatively, some, or all, of the cache for the processor set may be located “off chip.” In some computing environments, processor set 110 may be designed for working with qubits and performing quantum computing.

Computer readable program instructions are typically loaded onto computer 101 to cause a series of operational steps to be performed by processor set 110 of computer 101 and thereby effect a computer-implemented method, such that the instructions thus executed will instantiate the methods specified in flowcharts and/or narrative descriptions of computer-implemented methods included in this document (collectively referred to as “the inventive methods”). These computer readable program instructions are stored in various types of computer readable storage media, such as cache 121 and the other storage media discussed below. The program instructions, and associated data, are accessed by processor set 110 to control and direct performance of the inventive methods. In computing environment 100, at least some of the instructions for performing the inventive methods may be stored in block 200 in persistent storage 113.

Communication fabric 111 is the signal conduction path that allows the various components of computer 101 to communicate with each other. Typically, this fabric is made of switches and electrically conductive paths, such as the switches and electrically conductive paths that make up busses, bridges, physical input/output ports and the like. Other types of signal communication paths may be used, such as fiber optic communication paths and/or wireless communication paths.

Volatile memory 112 is any type of volatile memory now known or to be developed in the future. Examples include dynamic type random access memory (RAM) or static type RAM. Typically, the volatile memory 112 is characterized by random access, but this is not required unless affirmatively indicated. In computer 101, the volatile memory 112 is located in a single package and is internal to computer 101, but, alternatively or additionally, the volatile memory may be distributed over multiple packages and/or located externally with respect to computer 101.

Persistent storage 113 is any form of non-volatile storage for computers that is now known or to be developed in the future. The non-volatility of this storage means that the stored data is maintained regardless of whether power is being supplied to computer 101 and/or directly to persistent storage 113. Persistent storage 113 may be a read only memory (ROM), but typically at least a portion of the persistent storage allows writing of data, deletion of data and re-writing of data. Some familiar forms of persistent storage include magnetic disks and solid state storage devices. Operating system 122 may take several forms, such as various known proprietary operating systems or open-source Portable Operating System Interface type operating systems that employ a kernel. The code included in the cargo loading digital twin simulation program 150 typically includes at least some of the computer code involved in performing the inventive methods.

Peripheral device set 114 includes the set of peripheral devices of computer 101. Data communication connections between the peripheral devices and the other components of computer 101 may be implemented in various ways, such as Bluetooth connections, Near-Field Communication (NFC) connections, connections made by cables (such as universal serial bus (USB) type cables), insertion-type connections (for example, secure digital (SD) card), connections made through local area communication networks and even connections made through wide area networks such as the internet. In various embodiments, UI device set 123 may include components such as a display screen, speaker, microphone, wearable devices (such as goggles and smart watches), keyboard, mouse, printer, touchpad, game controllers, haptic devices, augmented reality devices, and virtual reality devices. Storage 124 is external storage, such as an external hard drive, or insertable storage, such as an SD card. Storage 124 may be persistent and/or volatile. In some embodiments, storage 124 may take the form of a quantum computing storage device for storing data in the form of qubits. In embodiments where computer 101 is required to have a large amount of storage (for example, where computer 101 locally stores and manages a large database) then this storage may be provided by peripheral storage devices designed for storing very large amounts of data, such as a storage area network (SAN) that is shared by multiple, geographically distributed computers. IoT sensor set 125 is made up of sensors that can be used in Internet of Things applications. For example, one sensor may be a thermometer and another sensor may be a motion detector. Other examples of sensors of which IoT sensor set 125 may be representative of include, by are not limited to, proximity sensors, accelerometers, infrared sensors, pressure sensors, light sensors, ultrasonic sensors, touch sensors, color sensors, humidity sensors, position sensors, magnetic sensors (e.g., Hall effect sensor), sound sensors (e.g., microphones), tilt sensors (e.g., gyroscopes), flow sensors, level sensors, strain sensors, and weight sensors.

Network module 115 is the collection of computer software, hardware, and firmware that allows computer 101 to communicate with other computers through WAN 102. Network module 115 may include hardware, such as modems or Wi-Fi signal transceivers, software for packetizing and/or de-packetizing data for communication network transmission, and/or web browser software for communicating data over the internet. In some embodiments, network control functions and network forwarding functions of network module 115 are performed on the same physical hardware device. In other embodiments (for example, embodiments that utilize software-defined networking (SDN)), the control functions and the forwarding functions of network module 115 are performed on physically separate devices, such that the control functions manage several different network hardware devices. Computer readable program instructions for performing the inventive methods can typically be downloaded to computer 101 from an external computer or external storage device through a network adapter card or network interface included in network module 115.

WAN 102 is any wide area network (for example, the internet) capable of communicating computer data over non-local distances by any technology for communicating computer data, now known or to be developed in the future. In some embodiments, the WAN 102 may be replaced and/or supplemented by local area networks (LANs) designed to communicate data between devices located in a local area, such as a Wi-Fi network. The WAN 102 and/or LANs typically include computer hardware such as copper transmission cables, optical transmission fibers, wireless transmission, routers, firewalls, switches, gateway computers and edge servers.

End user device (EUD) 103 is any computer system that is used and controlled by an end user and may take any of the forms discussed above in connection with computer 101. EUD 103 typically receives helpful and useful data from the operations of computer 101. For example, in a hypothetical case where computer 101 is designed to provide a recommendation to an end user, this recommendation would typically be communicated from network module 115 of computer 101 through WAN 102 to EUD 103. In this way, EUD 103 can display, or otherwise present, the recommendation to an end user. In some embodiments, EUD 103 may be a client device, such as thin client, heavy client, mainframe computer, desktop computer and so on.

Remote server 104 is any computer system that serves at least some data and/or functionality to computer 101. Remote server 104 may be controlled and used by the same entity that operates computer 101. Remote server 104 represents the machine(s) that collect and store helpful and useful data for use by other computers, such as computer 101. For example, in a hypothetical case where computer 101 is designed and programmed to provide a recommendation based on historical data, then this historical data may be provided to computer 101 from remote database 130 of remote server 104.

Public cloud 105 is any computer system available for use by multiple entities that provides on-demand availability of computer system resources and/or other computer capabilities, especially data storage (cloud storage) and computing power, without direct active management by the user. Cloud computing typically leverages sharing of resources to achieve coherence and economies of scale. The direct and active management of the computing resources of public cloud 105 is performed by the computer hardware and/or software of cloud orchestration module 141. The computing resources provided by public cloud 105 are typically implemented by virtual computing environments that run on various computers making up the computers of host physical machine set 142, which is the universe of physical computers in and/or available to public cloud 105. The virtual computing environments (VCEs) typically take the form of virtual machines from virtual machine set 143 and/or containers from container set 144. It is understood that these VCEs may be stored as images and may be transferred among and between the various physical machine hosts, either as images or after instantiation of the VCE. Cloud orchestration module 141 manages the transfer and storage of images, deploys new instantiations of VCEs and manages active instantiations of VCE deployments. Gateway 140 is the collection of computer software, hardware, and firmware that allows public cloud 105 to communicate through WAN 102.

Some further explanation of virtualized computing environments (VCEs) will now be provided. VCEs can be stored as “images.” A new active instance of the VCE can be instantiated from the image. Two familiar types of VCEs are virtual machines and containers. A container is a VCE that uses operating-system-level virtualization. This refers to an operating system feature in which the kernel allows the existence of multiple isolated user-space instances, called containers. These isolated user-space instances typically behave as real computers from the point of view of programs running in them. A computer program running on an ordinary operating system can utilize all resources of that computer, such as connected devices, files and folders, network shares, CPU power, and quantifiable hardware capabilities. However, programs running inside a container can only use the contents of the container and devices assigned to the container, a feature which is known as containerization.

Private cloud 106 is similar to public cloud 105, except that the computing resources are only available for use by a single enterprise. While private cloud 106 is depicted as being in communication with WAN 102, in other embodiments a private cloud may be disconnected from the internet entirely and only accessible through a local/private network. A hybrid cloud is a composition of multiple clouds of different types (for example, private, community, or public cloud types), often respectively implemented by different vendors. Each of the multiple clouds remains a separate and discrete entity, but the larger hybrid cloud architecture is bound together by standardized or proprietary technology that enables orchestration, management, and/or data/application portability between the multiple constituent clouds. In this embodiment, public cloud 105 and private cloud 106 are both part of a larger hybrid cloud.

Referring now to FIG. 2, an operational flowchart for a cargo loading digital twin simulation process 200 is depicted according to at least one embodiment. At 202, the cargo loading digital twin simulation program 150 captures property data related to a transport. Property data related to a transport, or transport property data, may relate to various dimensions (e.g., length, width, and height), statuses, and conditions of a transport. The transport property data may include, but is not limited to, transport length, transport width, transport height, transport storage area length, transport storage area width, transport storage area height, center of gravity while fully unloaded, transport carry capacity, number of wheels, individual wheel carry capacity, number of axles, position of each wheel, age of each tire, tread depth of each tire, pressure value of each tire, oil life status, vehicle mileage value, suspension age, suspension type, transport self-weight, individual component age, and individual component weight limit. In at least one embodiment, the cargo loading digital twin simulation program 150 may capture one or more items of transport property data through one or more sensors, such as IoT sensor set 125, capable of various forms of data capture, such as photographic capture, image analysis, pressure sensing, and/or weight sensing. In at least one other embodiment, the cargo loading digital twin simulation program 150 may capture or more items of transport property data by querying a repository, such as remote database 130. For example, the cargo loading digital twin simulation program 150 may obtain some items of transport property data (e.g., length, width, height, transport carry capacity, transport self-weight, number of wheels, number of axles, etc.) from a transport manufacturer's database, such as public cloud 105.

Then, at 204, the cargo loading digital twin simulation program 150 captures property data related to cargo items being loaded onto the transport. Property data related to cargo items, or cargo property data, may relate to dimensions (e.g., height, length, depth), shape, weight, center of gravity, stacked weight limit, fragility, and orientation of each surface of each cargo item. The cargo loading digital twin simulation program 150, utilizing one or more sensors (e.g., IoT sensor set 125 or any other communicatively coupled sensor) may capture the property data for each cargo item. Once the cargo property data is obtained, the cargo loading digital twin simulation program 150 may tag metadata-specific property data necessary for generating the loading plan to the cargo item. For example, the weight and center of gravity of each cargo item may be stored in a local repository, such as volatile memory 112 or persistent storage 113.

In at least one embodiment, the cargo loading digital twin simulation program 150 may capture the property data of each cargo item as the cargo item is being loaded onto the transport. For example, the cargo loading digital twin simulation program 150 may capture the cargo property data, such as dimensions, shape, and weight, using a photographic capture device and a scale, affixed to or embedded within the loading mechanism, while a cargo item is being loaded onto a transport using a loading mechanism, such as a crane or loading lift. In at least one other embodiment, the cargo loading digital twin simulation program 150 may capture the property data of each cargo item while the cargo item is in a queue to be loaded onto the transport. For example, the cargo loading digital twin simulation program 150 may identify each cargo item from a warehouse to be loaded onto a transport and capture the property data for each cargo item before it is brought to the transport.

In another embodiment, the cargo loading digital twin simulation program 150 may capture the cargo property data through one or more repositories, such as remote database 130. For example, the dimensions, shape, and weight of a packaged cargo item may be available through a manufacturer's database. In such a situation, the cargo loading digital twin simulation program 150 may access the database, perhaps using an application programming interface, to obtain the available property data and, using the available property data, derive other property data, such as a calculating the center of gravity.

In yet another embodiment, the cargo loading digital twin simulation program 150 may capture spatial information of the loading area surrounding the cargo items and the transport, such as the cantilever length and height of the loading platform.

Next, at 206, the cargo loading digital twin simulation program 150 generates a digital twin of the transport and each cargo item. As previously described, a digital twin is a virtual model of a physical entity that mirrors the characteristics of the item it represents. Utilizing the captured transport property data and the cargo property data, the cargo loading digital twin simulation program 150 may generate a digital twin of the unloaded transport and each cargo item to be loaded onto the transport. In at least one embodiment, the generated digital twin may exhibit the same characteristics of both the transport and each cargo item thereby allowing for an accurate simulation of how each entity will interact.

Then, at 208, the cargo loading digital twin simulation program 150 generates a loading plan for the transport. While generating the digital twin simulation, the cargo loading digital twin simulation program 150 may consider how each cargo item will affect the transport, and any other earlier loaded cargo items, during the loading process. The cargo loading digital twin simulation program 150 may iterate loading of various cargo items in different orders through the digital twin simulation in order to identify a center of gravity that best fits an even wear on the transport and its components as well as ensures the safety of the transport while traversing a travel route. For example, cargo items A through E may be readied for loading on a transport. If a transport only has adequate storage space to stack the cargo items one on top of the other, the cargo loading digital twin simulation program 150 may iterate through the 120 various iterations to determine which orientation of loading the transport yields the lowest center of gravity and, thereby, the safest means of transport. In another situation where cargo items A through E can be oriented around the storage space of a transport but cannot be placed on top of one another due to either space or weight restrictions of each cargo item, the cargo loading digital twin simulation program 150 may determine the orientation of the cargo items in the storage space that yields the most even distribution so as to avoid an uneven wear on the transport's tires and/or doesn't exceed the weight capacity of any one, or any combination of, tires, wheels, or axles. In yet another example, the cargo loading digital twin simulation program 150 may iterate through various loading orientations and stacking of cargo items A through E (or any number of cargo items permitted by the space and/or weight limits allowed by the transport) to achieve a loading orientation that yields the most even wear on the transport components with the lowest center of gravity.

Upon determining the orientation of the cargo items within the transport storage space, the cargo loading digital twin simulation program 150 may generate a loading plan of each cargo item onto the transport. The loading plan may be a series of steps that identify a location within the storage area of the transport a specific item of cargo will be placed and in which order the various cargo items will be placed. For example, the cargo loading digital twin simulation program 150 may generate a coordinate map of the transport storage area and indicate a location at which each cargo item will be placed. Upon identifying the location of each cargo item that yields the most even wear and lowest center of gravity, the cargo loading digital twin simulation program 150 may identify the series of steps needed to load the physical transport in order to recreate the digital twin.

In at least one embodiment, the cargo loading digital twin simulation program 150 may generate a set of instructions, either manually readable in natural language by a human loading operator or digitally executable by a program. For example, in the situation where the set of instructions are manually readable in a natural language by a human, the cargo loading digital twin simulation program 150 may generate instructions that order the placement of cargo item A in location A, cargo item B in location B, etc. until all cargo items are loaded. In a similar example where the set of instructions are to be executable by a program, the cargo loading digital twin simulation program 150 may generate computer code in any ingestible language understood by a computer loading device, such as a robotic crane or unmanned forklift, in order to execute the loading plan effectively.

In another embodiment, the cargo loading digital twin simulation program 150 may gather various data items related to the route the transport will traverse to its destination, such as weather conditions and roadway conditions, and utilize those data items when generating the loading plan.

Next, at 210, the cargo loading digital twin simulation program 150 transmits the generated loading plan to a user. Once the loading plan has been generated in the proper format, the cargo loading digital twin simulation program 150 may transmit the loading plan to a proper location according to the format in which it was generated. For example, if the loading plan is generated for execution by a robotic cargo loading device, the cargo loading digital twin simulation program 150 may transmit the generated loading plan, in executable computing code, to the robotic cargo loading device for execution by processor set 110. Similarly, if the generated loading plan is to be performed manually by a human, the cargo loading digital twin simulation program 150 may transmit the generated loading plan as instructions in a textual and/or visual format to a device, such as computer 101 or end user device 103, through WAN 102 for depiction on a device display screen. In at least on embodiment, the cargo loading digital twin simulation program 150 may allow a textual and/or visually formatted loading plan to be interacted with by a user through user interactions on the device display screen.

In another embodiment, during manual loading, the cargo loading digital twin simulation program 150 may utilize an augmented reality or virtual reality system to aid the user manually loading the transport to visualize the placement of each cargo item. While using an augmented reality or virtual reality system, the cargo loading digital twin simulation program 150 may display an outline of the location in which the cargo item should be placed. Furthermore, the cargo loading digital twin simulation program 150 may display, through the augmented reality system or virtual reality system, various data items related to each cargo item, such as height, width, depth, weight, and location of the center of gravity.

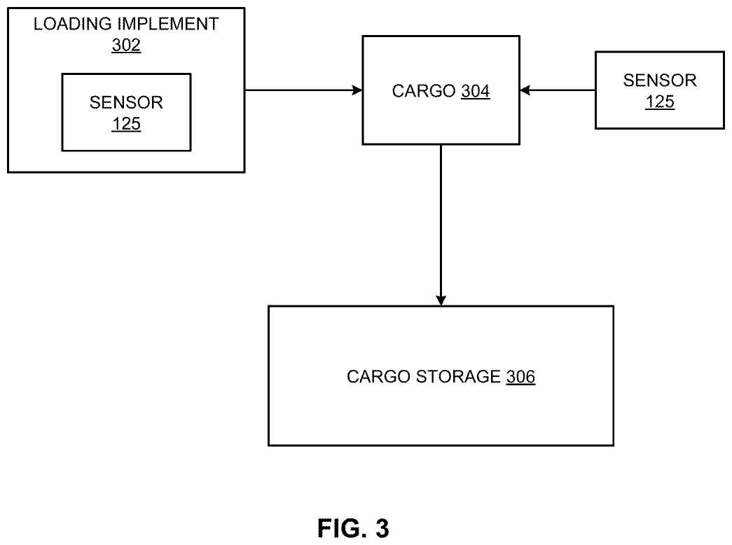

Referring now to FIG. 3, an exemplary block diagram of digital twin simulation for a cargo loading system according to at least one embodiment. As one or more items of cargo 304 are awaiting to be loaded, one or more sensors, such as IoT sensor set 125, may capture property data related to the cargo 304. The one or more sensors may be independent of any other device or may be embedded within another device, such as one or more cameras deployed around a loading area that captures dimensions of cargo 304 or one or more scales embedded in the floor of the loading area capable of determining the weight of each item of cargo 304. For example, a loading crane, such as a loading implement 302, may have a sensor, such as a scale or a camera, capable of capturing data properties, such as height, width, depth, and weight, of the cargo 304. Similarly, the dimensions of cargo storage 306, which may be a storage space attached to or capable of transport by a transport vehicle, may be obtained either by sensors, such as IoT sensor set 125, and/or gathered through a database, such as remote database 130. A cargo loading plan may be generated based on the various property data of cargo 304 and cargo storage 306 consistent with preconfigured specifications, such as lowest center of gravity or most even distribution of weight. Each item of cargo 304 may be subsequently loaded to cargo storage 306 according to the generated cargo loading plan. In at least one embodiment, the cargo loading digital twin simulation program 150 supplement the cargo loading plan with additional weight separate from the cargo 304 to achieve an optimized plan according to the preconfigured specifications. For example, if the calculated center of gravity remains above a threshold for safe traversal of a route to a destination, the cargo loading digital twin simulation program 150 may proscribe additional weight to the cargo storage 306 in specific locations to lower the center of gravity. Similarly, if each item of cargo 304 is not evenly distributed, the cargo loading digital twin simulation program 150 may determine specific locations to place additional weight in the cargo storage 306 that allows for more even weight distribution and, thereby, more even wear on the transport components.

It may be appreciated that FIGS. 2 and 3 provide only an illustration of one implementation and do not imply any limitations with regard to how different embodiments may be implemented. Many modifications to the depicted environments may be made based on design and implementation requirements. In at least one embodiment, the cargo loading digital twin simulation program 150 may generate an unloading plan during the generation of the loading plan. The generated unloading plan may be a series of step by which the cargo items are to be unloaded from the transport so as to prevent unbalancing the transport in a manner that can damage the remaining loaded cargo items and/or the transport being unloaded.

In another embodiment, the cargo loading digital twin simulation program 150 may present recommendations for weighting the transport during movement to maintain a consistent center of gravity based on the calculated location of the center of gravity according to the generated loading plan and the predicted transport route to a destination location. For example, if the route by which the transport is to traverse to the destination has a sharp turn that may otherwise affect the center of gravity of the transport calculated by the cargo loading digital twin simulation program 150 during generation of the loading plan, the cargo loading digital twin simulation program 150 may determine that loading extra weight, similar to basalt in a cargo ship, may prevent an unsafe unbalancing of the center of gravity and potential damage to one or more loaded cargo items and/or the transport.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A processor-implemented method, the method comprising:
capturing, by a processor, a plurality of property data related to a transport;
capturing a plurality of property data related to a plurality of cargo items;
generating a digital twin simulation of the transport and each cargo item; and
generating a loading plan of each cargo item onto the transport based on the generated digital twin simulation.

2. The method of claim 1, wherein the generated loading plan is a series of steps plan to load the plurality of cargo items onto the transport with a lowest resultant center of gravity.

3. The method of claim 1, wherein the generated loading plan is a series of steps to load the plurality of cargo items onto the transport with an optimized distribution of weight throughout a storage area of the transport.

4. The method of claim 1, wherein the plurality of property data related to each cargo item in the plurality of cargo items is captured by one or more sensors affixed to or embedded within a loading device.

5. The method of claim 1, further comprising:
transmitting the generated loading plan to a user.

6. The method of claim 1, wherein the plurality of property data related to the transport is selected from a group consisting of transport length, transport width, transport height, transport storage area length, transport storage area width, transport storage area height, center of gravity while fully unloaded, transport carry capacity, number of wheels, individual wheel carry capacity, number of axles, position of each wheel, age of each tire, tread depth of each tire, pressure value of each tire, oil life status, vehicle mileage value, suspension age, suspension type, transport self-weight, individual component age, and individual component weight limit.

7. The method of claim 1, wherein the plurality of property data related to the plurality of cargo items is selected from a group consisting of dimensions, shape, weight, center of gravity, stacked weight limit, fragility, and orientation of each surface of each cargo item.

8. A computer system, the computer system comprising:
one or more processors, one or more computer-readable memories, one or more computer-readable tangible storage medium, and program instructions stored on at least one of the one or more tangible storage medium for execution by at least one of the one or more processors via at least one of the one or more memories, wherein the computer system is capable of performing a method comprising:
capturing a plurality of property data related to a transport;
capturing a plurality of property data related to a plurality of cargo items;
generating a digital twin simulation of the transport and each cargo item; and
generating a loading plan of each cargo item onto the transport based on the generated digital twin simulation.

9. The computer system of claim 8, wherein the generated loading plan is a series of steps plan to load the plurality of cargo items onto the transport with a lowest resultant center of gravity.

10. The computer system of claim 8, wherein the generated loading plan is a series of steps to load the plurality of cargo items onto the transport with an optimized distribution of weight throughout a storage area of the transport.

11. The computer system of claim 8, wherein the plurality of property data related to each cargo item in the plurality of cargo items is captured by one or more sensors affixed to or embedded within a loading device.

12. The computer system of claim 8, further comprising:
transmitting the generated loading plan to a user.

13. The computer system of claim 8, wherein the plurality of property data related to the transport is selected from a group consisting of transport length, transport width, transport height, transport storage area length, transport storage area width, transport storage area height, center of gravity while fully unloaded, transport carry capacity, number of wheels, individual wheel carry capacity, number of axles, position of each wheel, age of each tire, tread depth of each tire, pressure value of each tire, oil life status, vehicle mileage value, suspension age, suspension type, transport self-weight, individual component age, and individual component weight limit.

14. The computer system of claim 8, wherein the plurality of property data related to the plurality of cargo items is selected from a group consisting of dimensions, shape, weight, center of gravity, stacked weight limit, fragility, and orientation of each surface of each cargo item.

15. A computer program product, the computer program product comprising:
one or more computer-readable tangible storage medium and program instructions stored on at least one of the one or more tangible storage medium, the program instructions executable by a processor capable of performing a method, the method comprising:
capturing a plurality of property data related to a transport;
capturing a plurality of property data related to a plurality of cargo items;
generating a digital twin simulation of the transport and each cargo item; and
generating a loading plan of each cargo item onto the transport based on the generated digital twin simulation.

16. The computer program product of claim 15, wherein the generated loading plan is a series of steps plan to load the plurality of cargo items onto the transport with a lowest resultant center of gravity.

17. The computer program product of claim 15, wherein the generated loading plan is a series of steps to load the plurality of cargo items onto the transport with an optimized distribution of weight throughout a storage area of the transport.

18. The computer program product of claim 15, wherein the plurality of property data related to each cargo item in the plurality of cargo items is captured by one or more sensors affixed to or embedded within a loading device.

19. The computer program product of claim 15, further comprising:
transmitting the generated loading plan to a user.

20. The computer program product of claim 15, wherein the plurality of property data related to the transport is selected from a group consisting of transport length, transport width, transport height, transport storage area length, transport storage area width, transport storage area height, center of gravity while fully unloaded, transport carry capacity, number of wheels, individual wheel carry capacity, number of axles, position of each wheel, age of each tire, tread depth of each tire, pressure value of each tire, oil life status, vehicle mileage value, suspension age, suspension type, transport self-weight, individual component age, and individual component weight limit.
